(19) United States
(12) Patent Application Publication
(10) Pub. No.: US 2024/0328033 A1
(43) Pub. Date: Oct. 3, 2024

(54) FILM FORMING METHOD AND FILM FORMING APPARATUS

(71) Applicant: Tokyo Electron Limited, Tokyo (JP)

(72) Inventors: Tuhin Shuvra BASU, Yamanashi (JP); Hiroto FUJIKAWA, Yamanashi (JP); Keita KUMAGAI, Yamanashi (JP); Yoshihiro TAKEZAWA, Yamanashi (JP); Daisuke SUZUKI, Yamanashi (JP)

(21) Appl. No.: 18/609,525

(22) Filed: Mar. 19, 2024

(30) Foreign Application Priority Data
Mar. 31, 2023 (JP) 2023-057831

(51) Int. Cl. C30B 29/06

(52) U.S. Cl. CPC C30B 29/06

(57) ABSTRACT

A film forming method for forming a silicon film on a substrate, includes supplying a silane-based gas and a termination gas to the substrate during a period. The termination gas includes an element having an electronegativity lower than an electronegativity of hydrogen, and the supplying includes terminating a dangling bond of silicon in the silicon film with the element.

### CROSS-REFERENCE TO RELATED APPLICATIONS

This application is based upon and claims priority to Japanese Patent Application No. 2023-057831, filed on Mar. 31, 2023, the entire contents of which are incorporated herein by reference.

### BACKGROUND

### 1. Field of the Invention

The present disclosure relates to film forming methods and film forming apparatuses.

### 2. Description of the Related Art

A technique for forming a seed layer and an amorphous silicon film in this order on a base is known (refer to Japanese Laid-Open Patent Publication No. 2011-249764, for example).

### SUMMARY

One aspect of the present disclosure provides a technique capable of reducing defects included in a silicon film.

A film forming method for forming a silicon film on a substrate according to one aspect of the present disclosure includes supplying a silane-based gas and a termination gas to the substrate during a period, wherein the termination gas includes an element having an electronegativity lower than an electronegativity of hydrogen, and the supplying includes terminating a dangling bond of silicon in the silicon film with the element.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flow chart illustrating a film forming method according to one embodiment;

FIG. 2 is a sequence diagram illustrating the film forming method according to one embodiment;

FIG. 3A, FIG. 3B, and FIG. 3C are cross sectional views illustrating the film forming method according to one embodiment;

FIG. 4A and FIG. 4B are diagrams illustrating surface states of a silicon film during a silicon film forming process;

FIG. 5 is a cross sectional view illustrating a film forming apparatus according to one embodiment;

FIG. 6 is a diagram (part 1) illustrating a PL spectrum of an amorphous silicon film;

FIG. 7 is a diagram (part 2) illustrating the PL spectrum of the amorphous silicon film; and

FIG. 8 is a diagram (part 3) illustrating the PL spectrum of the amorphous silicon film.

### DETAILED DESCRIPTION

Non-limiting embodiments and exemplary implementations of the present disclosure will be described below with reference to the accompanying drawings. In all the accompanying drawings, the same or corresponding members or parts are designated by the same or corresponding reference numerals, and a redundant description thereof will be omitted.

### [Film Forming Method]

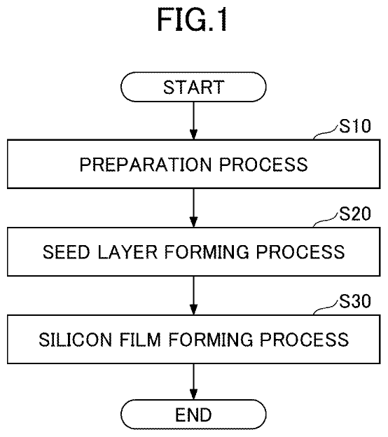

A film forming method according to one embodiment will be described with reference to FIG. 1 through FIG. 4B. As illustrated in FIG. 1, the film forming method according to the embodiment includes a preparation process (or step) S10, a seed layer forming process (or step) S20, and a silicon film forming process (or step) S30.

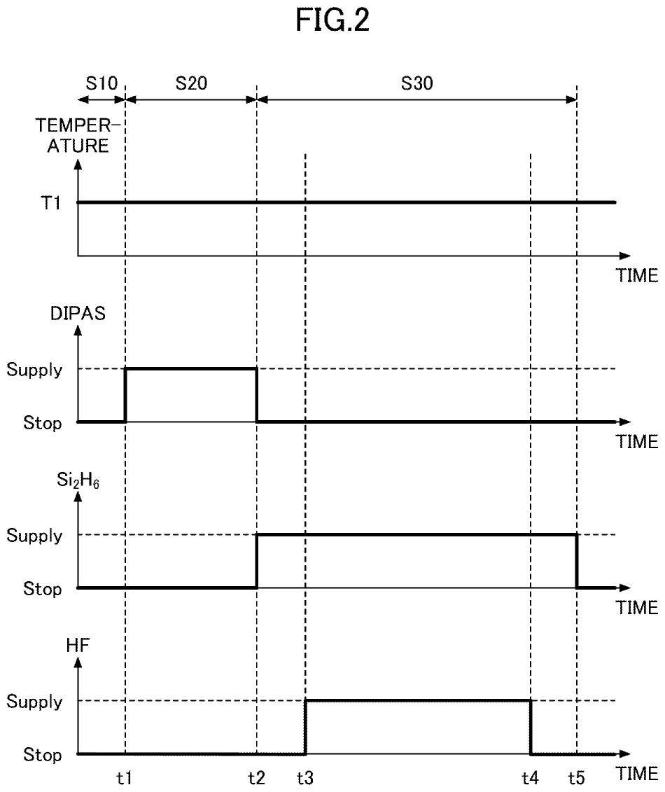

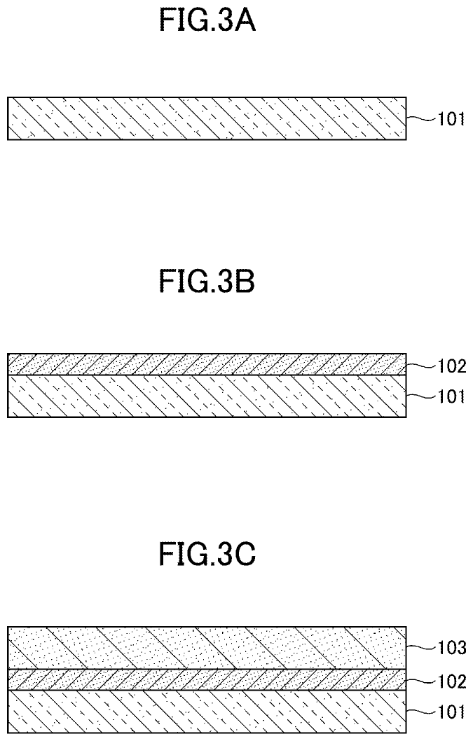

The preparation process S10 includes preparing a substrate 101 as illustrated in FIG. 3A. The substrate 101 may be a semiconductor wafer, such as a silicon wafer or the like, for example. As illustrated in FIG. 2, the preparation process S10 includes maintaining the substrate 101 at a first temperature T1. The first temperature T1 is 380° C., for example.

The seed layer forming process S20 is performed after the preparation process S10. As illustrated in FIG. 2, the seed layer forming process S20 includes maintaining the substrate 101 at the first temperature T1. In the seed layer forming process S20, supply of a di-isopropyl-aminosilane (DIPAS) gas to the substrate 101 is started at a time t1, the supply of the DIPAS gas is continued until a time t2, and the supply of the DIPAS gas is stopped at a time t2. That is, the seed layer forming process S20 includes supplying the DIPAS gas to the substrate 101 during a period from the time t1 to the time t2. Thus, as illustrated in FIG. 3B, a seed layer 102 is formed on the substrate 101. The DIPAS gas is an example of an aminosilane-based gas. The seed layer forming process S20 may be omitted.

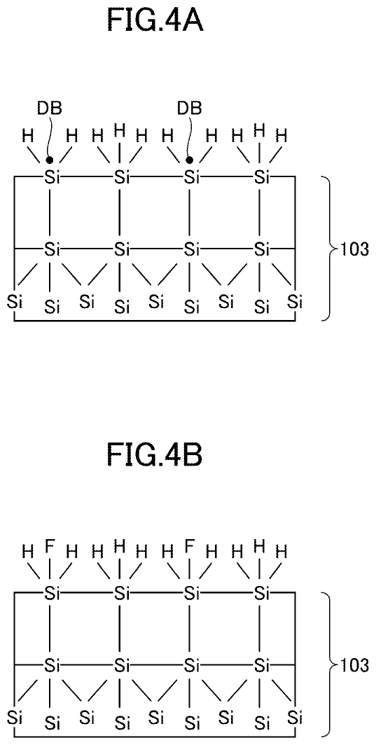

The silicon film forming process S30 is performed after the seed layer forming process S20. As illustrated in FIG. 2, the silicon film forming process S30 includes maintaining the substrate 101 at the first temperature T1. In the silicon film forming process S30, supply of a disilane (Si₂H₆) gas to the substrate 101 is started at the time t2, the supply of the disilane gas is continued until a time t5, and the supply of the disilane gas is stopped at the time t5. In the silicon film forming process S30, supply of a hydrogen fluoride (HF) gas to the substrate 101 is started at a time t3, the supply of the hydrogen fluoride gas is continued until a time t4, and the supply of the hydrogen fluoride gas is stopped at the time t4. That is, in the silicon film forming process S30, the disilane gas is supplied to the substrate 101, without supplying the hydrogen fluoride gas from the time t2 to the time t3 and from the time t4 to the time t5, and the disilane gas and the hydrogen fluoride gas are simultaneously supplied from the time t3 to the time t4. As a result, as illustrated in FIG. 3C, an amorphous silicon (a-Si) film 103 is formed on the seed layer 102. When forming the amorphous silicon film 103, silicon (Si) having a dangling bond DB which is not terminated with hydrogen may be present, as illustrated in FIG. 4A. Accordingly, the disilane gas and the hydrogen fluoride gas are simultaneously supplied during at least a part of (that is, during a period amounting to an entire duration of) the silicon film forming process S30, so that the dangling bond DB of silicon in the amorphous silicon film 103 is terminated with fluorine (F) of the hydrogen fluoride gas, as illustrated in FIG. 4B. Thus, it is possible to reduce defects included in the amorphous silicon film 103.

In the silicon film forming process S30, the disilane gas and the hydrogen fluoride gas may be supplied simultaneously during the entire duration thereof. In the silicon film forming process S30, the disilane gas may be supplied without supplying the hydrogen fluoride gas in a first half of the entire duration thereof, and the disilane gas and the hydrogen fluoride gas may be simultaneously supplied in a second half of the entire duration thereof. In the silicon film forming process S30, the disilane gas and the hydrogen fluoride gas may be simultaneously supplied in the first half of the entire duration thereof, and the disilane gas may be supplied without supplying the hydrogen fluoride gas in the second half of the entire duration thereof. That is, the disilane gas may be supplied without supplying the hydrogen fluoride gas during a predetermined period within the silicon film forming process S30.

As described above, according to the film forming method of the embodiment, in the silicon film forming process S30, the disilane gas and the hydrogen fluoride gas are simultaneously supplied to the substrate 101, and the dangling bond DB of silicon in the amorphous silicon film 103 is terminated with the fluorine of the hydrogen fluoride gas. Thus, it is possible to reduce the defects included in the amorphous silicon film 103.

The film forming method according to the embodiment can be suitably used when forming a channel layer of a three dimensional NAND memory, for example. In a case where the channel layer of the three dimensional NAND memory is formed, an electron mobility of the channel layer can be improved, by subjecting the amorphous silicon film 103 to a heat treatment to form a polysilicon film having large crystal grains. However, during a specific process for a case where a thickness of the amorphous silicon film 103 is small or the like, the size of the crystal grains cannot be increased infinitely. Hence, by reducing the defects included in the amorphous silicon film 103 by the film forming method according to the embodiment, it is possible to improve the electron mobility of the channel layer.

### [Film Forming Apparatus]

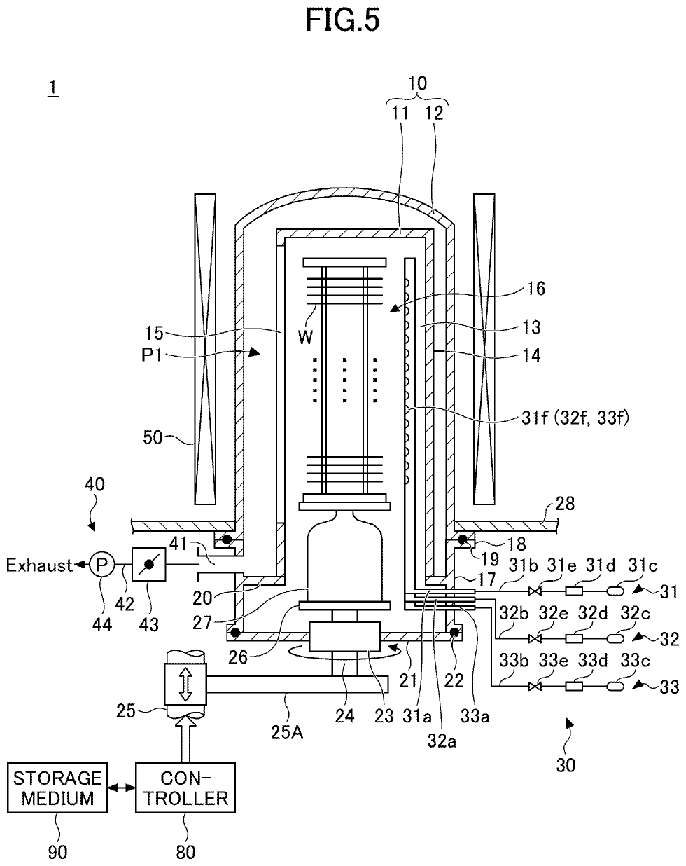

A film forming apparatus 1 according to the embodiment will be described with reference to FIG. 5. As illustrated in FIG. 5, the film forming apparatus 1 is a batch-type apparatus that simultaneously performs processes on a plurality of substrates W.

The film forming apparatus 1 includes a processing chamber 10, a gas supply 30, an exhaust 40, a heater 50, and a controller 80.

The inside of the processing chamber 10 can be depressurized. The processing chamber 10 accommodates the substrates W therein. The processing chamber 10 includes an inner tube 11 and an outer tube 12. The inner tube 11 and the outer tube 12 have a cylindrical shape with a ceiling and an open lower end. The outer tube 12 covers an outside of the inner tube 11. The inner tube 11 and the outer tube 12 have a coaxially arranged double tube structure. The inner tube 11 and the outer tube 12 are formed of a heat resistant material, such as quartz or the like.

The ceiling of the inner tube 11 may be flat, for example. An accommodating part 13 for accommodating gas nozzles along a longitudinal direction (vertical direction) thereof is formed on one side of the inner tube 11. For example, a part of a sidewall of the inner tube 11 protrudes outward to form a protrusion 14, and the inside of the protrusion 14 is formed as the accommodating part 13.

A rectangular opening 15 is formed in the sidewall of the inner tube 11 on the opposite side opposing the accommodating part 13 along the longitudinal direction (vertical direction) thereof.

The opening 15 is a gas exhaust port formed to enable the gas inside the inner tube 11 to be exhausted. A length of the opening 15 is the same as a length of a boat 16, or is formed to be longer than the length of the boat 16 by extending in the vertical direction.

A lower end of the processing chamber 10 is supported by a cylindrical manifold 17. The manifold 17 is formed of stainless steel, for example. A flange 18 is formed on an upper end of the manifold 17. The flange 18 supports the lower end of the outer tube 12. A seal member 19, such as an O-ring or the like, is provided between the flange 18 and the lower end of the outer tube 12. Thus, the inside of the outer tube 12 is maintained airtight.

An annular support 20 is provided on an inner wall at an upper portion of the manifold 17. The support 20 supports the lower end of the inner tube 11. A lid 21 is attached airtight to an opening at the lower end of the manifold 17 via a seal member 22, such as an O-ring or the like. Thus, the opening at the lower end of the processing chamber 10, that is, the opening of the manifold 17, is closed airtight. The lid 21 is formed of stainless steel, for example.

A rotating shaft 24 is provided to penetrate a center of the lid 21 via a magnetic fluid seal 23. A lower portion of the rotating shaft 24 is rotatably supported on an arm 25A of an elevator mechanism 25 including a boat elevator.

A rotary plate 26 is provided on an upper end of the rotating shaft 24. The boat 16, configured to hold the substrates W via a quartz insulating table 27, is placed on the rotary plate 26. The boat 16 is rotated by rotating the rotating shaft 24. The boat 16 moves up and down (vertically) integrally with the lid 21, by raising and lowering the elevator mechanism 25. Thus, the boat 16 is inserted into and removed, that is, loaded into and unloaded from the processing chamber 10. The boat 16 can be accommodated inside the processing chamber 10. The boat 16 holds the plurality of (for example, 50 to 150) substrates W in an approximately horizontal state at intervals along the vertical direction.

The gas supply 30 is configured to introduce various processing gases used in the film forming method described above into the inner tube 11. The gas supply 30 includes a DIPAS supply 31, a disilane supply 32, and a hydrogen fluoride supply 33.

The DIPAS supply 31 includes a DIPAS supply pipe 31a inside the processing chamber 10, and a DIPAS supply path 31b outside the processing chamber 10. The DIPAS supply path 31b is provided with a DIPAS source 31c, a mass flow controller 31d, and a valve 31e in this order from an upstream side to a downstream side along a gas flowing direction. Thus, a supply timing of the DIPAS gas from the DIPAS source 31c is controlled by the valve 31e, and a flow of the DIPAS gas is adjusted to a predetermined flow rate by the mass flow controller 31d. The DIPAS gas flows from the DIPAS supply path 31b to the DIPAS supply pipe 31a, and is discharged from the DIPAS supply pipe 31a into the processing chamber 10.

The disilane supply 32 includes a disilane supply pipe 32a inside the processing chamber 10, and a disilane supply path 32b outside the processing chamber 10. A disilane source 32c, a mass flow controller 32d, and a valve 32e are provided in the disilane supply path 32b in this order from an upstream side to a downstream side along a gas flowing direction. Thus, a supply timing of the disilane gas from the disilane source 32c is controlled by the valve 32e, and a flow of the disilane gas is adjusted to a predetermined flow rate by the mass flow controller 32d. The disilane gas flows from the disilane supply path 32b to the disilane supply pipe 32a, and is discharged from the disilane supply pipe 32a into the processing chamber 10.

The hydrogen fluoride supply 33 includes a hydrogen fluoride supply pipe 33a inside the processing chamber 10, and a hydrogen fluoride supply path 33b outside the processing chamber 10. The hydrogen fluoride supply path 33b is provided with a hydrogen fluoride source 33c, a mass flow controller 33d, and a valve 33e in this order from an upstream side to a downstream side along a gas flowing direction. Thus, a supply timing of the hydrogen fluoride gas from the hydrogen fluoride source 33c is controlled by the valve 33e, and the flow of the hydrogen fluoride gas is adjusted to a predetermined flow rate by the mass flow controller 33d. The hydrogen fluoride gas flows from the hydrogen fluoride supply path 33b to the hydrogen fluoride supply pipe 33a, and is discharged from the hydrogen fluoride supply pipe 33a into the processing chamber 10.

Each of the gas supply pipes (the DIPAS supply pipe 31a, the disilane supply pipe 32a, and the hydrogen fluoride supply pipe 33a) is fixed to the manifold 17. Each of the gas supply pipes is formed of quartz, for example. Each of the gas supply pipes extends linearly along the vertical direction at a position near the inner tube 11, and is bent in an L shape inside the manifold 17 to extend in a horizontal direction so as to penetrate the manifold 17. The gas supply pipes are arranged in a circumferential direction of the inner tube 11, and are formed to the same height.

A plurality of DIPAS discharge ports 31f are provided in a portion of the DIPAS supply pipe 31a located inside the inner tube 11. A plurality of disilane discharge ports 32f are provided in a portion of the disilane supply pipe 32a located inside the inner tube 11. A plurality of hydrogen fluoride discharge ports 33f are provided in a portion of the hydrogen fluoride supply pipe 33a located inside the inner tube 11.

The discharge ports (the DIPAS discharge ports 31f, the disilane discharge ports 32f, and the hydrogen fluoride discharge ports 33f) are formed at predetermined intervals along the direction in which the corresponding gas supply pipe extends. Each of the discharge ports discharges the gas in the horizontal direction. The interval between the adjacent discharge ports is set to be the same as the interval between the adjacent substrates W held by the boat 16, for example. The position of each discharge port along a height direction (vertical direction) is set to an intermediate position between the adjacent substrates W that are adjacent to each other along the vertical direction. Hence, each discharge port can efficiently supply the gas to an opposing surface between the adjacent substrates W.

The gas supply 30 may mix a plurality of kinds of gases and discharge the mixed gas from a single gas supply pipe. The gas supply pipes (the DIPAS supply pipe 31a, the disilane supply pipe 32a, and the hydrogen fluoride supply pipe 33a) may have mutually different shapes and arrangements. The film forming apparatus 1 may further include a gas supply pipe configured to supply another gas, in addition to the DIPAS gas, the disilane gas, and the hydrogen fluoride gas.

The exhaust 40 exhausts the gas discharged from the inside of the inner tube 11 through the opening 15, and discharged from a gas outlet 41 through a space P1 between the inner tube 11 and the outer tube 12. The gas outlet 41 is formed in a sidewall at the upper portion of the manifold 17 above the support 20. An exhaust passage 42 is connected to the gas outlet 41. A pressure regulating valve 43 and a vacuum pump 44 are successively provided in the exhaust passage 42, so that the gas inside of the processing chamber 10 can be exhausted.

The heater 50 is provided around the outer tube 12. The heater 50 is provided on a base plate 28, for example. The heater 50 has a cylindrical shape so as to cover the outer tube 12. The heater 50 includes a heating element, for example, and heats each of the substrates W inside the processing chamber 10.

The controller 80 controls the operation of various parts or components of the film forming apparatus 1. The controller 80 may be a computer, for example. A program which, when executed by the computer, causes the computer to perform the operations of the various parts or components of the film forming apparatus 1, is stored in the storage medium 90. The storage medium 90 may be a flexible disk, a compact disk, a hard disk, a flash memory, a digital versatile disk (DVD), or the like. The storage medium 90 may be any suitable non-transitory computer-readable storage medium capable of storing one or more programs.

### [Operation of Film Forming Apparatus]

The operations of the film forming apparatus 1 when performing the film forming method according to the embodiment will be described.

First, the controller 80 controls the elevator mechanism 25 to load the boat 16 holding the plurality of substrates W into the processing chamber 10, and closes the opening at the lower end of the processing chamber 10 with the lid 21 to seal the processing chamber 10 airtight. Then, the controller 80 controls the exhaust 40 to depressurize the inside of the processing chamber 10, and controls the heater 50 to adjust the temperature of the substrates W to the first temperature T1. Each of the substrates W may be the substrate 101 described above.

Next, the controller 80 controls the gas supply 30, the exhaust 40, and the heater 50 so as to perform the seed layer forming process S20. More particularly, first, the controller 80 controls the gas supply 30 to supply the DIPAS gas into the processing chamber 10 in a state where the temperature of the substrates W is maintained at the first temperature T1 by controlling the heater 50, and controls the exhaust 40 to maintain the inside of the processing chamber 10 at a processing pressure. Thus, the seed layer 102 is formed on the substrate 101.

Next, the controller 80 controls the gas supply 30, the exhaust 40, and the heater 50 so as to perform the silicon film forming process S30. More particularly, first, the controller 80 controls the gas supply 30 to supply the disilane gas into the processing chamber 10 in a state where the temperature of the substrates W is maintained at the first temperature T1 by controlling the heater 50, and controls the exhaust 40 to maintain the inside of the processing chamber 10 at a processing pressure. In this state, the controller 80 controls the gas supply 30 to supply the hydrogen fluoride gas into the processing chamber 10 during at least a part of the period in which the disilane gas is supplied into the processing chamber 10. Hence, the amorphous silicon film 103 is formed on the seed layer 102. In this case, the dangling bond DB of silicon in the amorphous silicon film 103 is terminated by the fluorine (F) of the hydrogen fluoride gas. Thus, it is possible to reduce the defects included in the amorphous silicon film 103.

Next, the controller 80 raises the pressure inside the processing chamber 10 to the atmospheric pressure, and lowers the temperature inside the processing chamber 10 to an unloading temperature, before controlling the elevator mechanism 25 to unload the boat 16 from the processing chamber 10.

### [Exemplary Implementations]

A description will be given of exemplary implementations in which it was confirmed that the defects included in the amorphous silicon film can be reduced by the film forming method according to the embodiment.

In the exemplary implementations, a silicon wafer having a silicon oxide film (thermal oxide film) on a surface thereof was prepared, the prepared silicon wafer was accommodated inside the processing chamber 10 of the film forming apparatus 1, and an amorphous silicon film was formed on the silicon oxide film under the following conditions A, B, and C. Next, a photo-luminescence (PL) intensity of the amorphous silicon film formed under each of the conditions A, B, and C was measured using a photoluminescence (PL) technique.

### (Condition A)

Under the condition A, the disilane gas and the hydrogen fluoride gas were simultaneously supplied with respect to the prepared substrate, so as to form the amorphous silicon film having a thickness of 30 nm on the silicon oxide film.

### (Condition B)

Under the condition B, the disilane gas and the hydrogen fluoride gas were alternately supplied with respect to the prepared substrate, so as to form the amorphous silicon film having a thickness of 30 nm on the silicon oxide film.

### (Condition C)

Under the condition C, the disilane gas was supplied with respect to the prepared substrate without supplying the hydrogen fluoride gas, so as to form the amorphous silicon film having a thickness of 30 nm on the silicon oxide film.

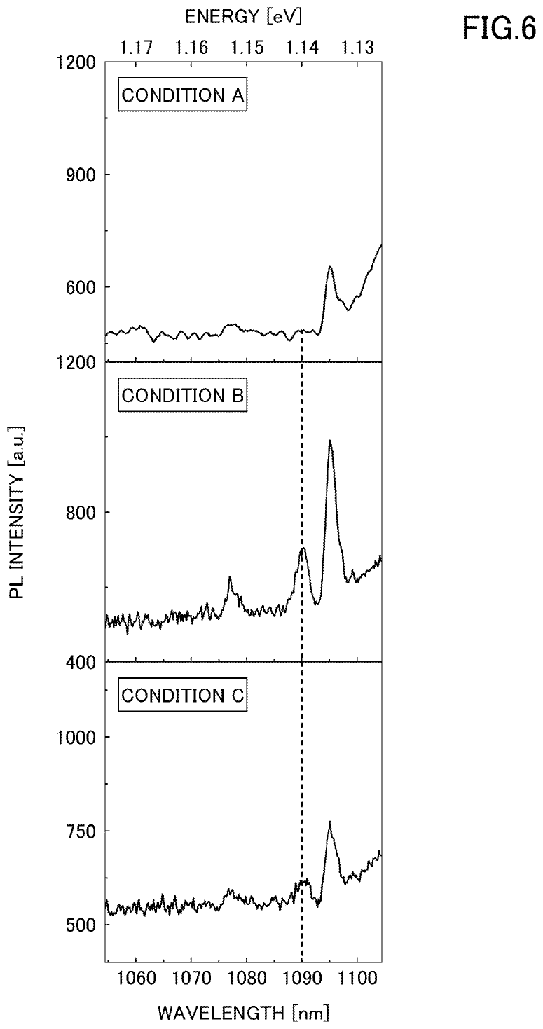

FIG. 6 through FIG. 8 are diagrams illustrating PL spectra of the amorphous silicon films. In FIG. 6 through FIG. 8, the abscissa represents a wavelength [nm] and an energy [eV], and the vertical axis represents PL intensity [a. u.], where “a. u.” indicates “arbitrary units”. FIG. 6 through FIG. 8 illustrate the results for the conditions A, B, and C in this order from an upper end of the graphs, respectively.

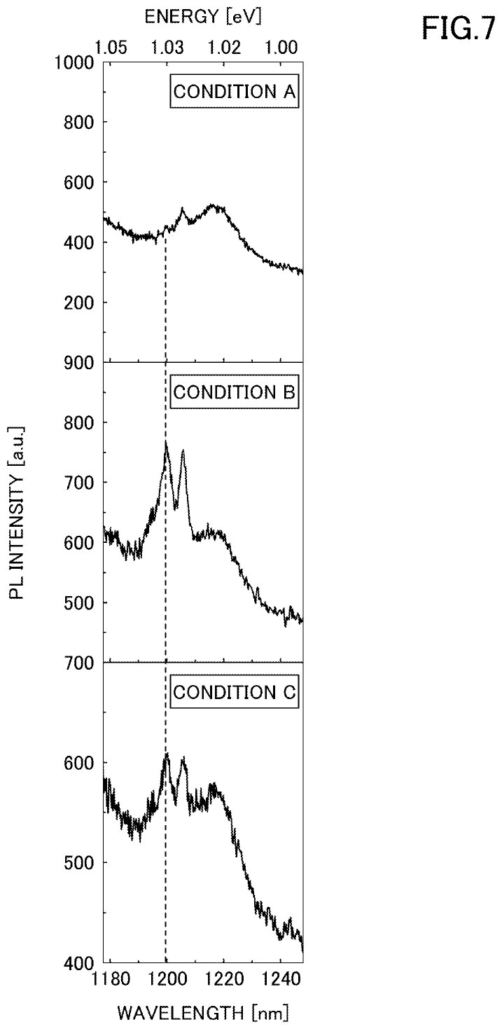

As illustrated in FIG. 6, it was found that a peak of the PL intensity at 1.14 eV is detected under the conditions B and C, whereas the peak of the PL intensity at 1.14 eV disappears under the condition A. As illustrated in FIG. 7, it was found that the a of the PL intensity at 1.034 eV is detected under the conditions B and C, whereas the peak of the PL intensity at 1.034 eV disappears under the condition A. From these results, it may be regarded that some of the defects included in the amorphous silicon film disappeared when the disilane gas and the hydrogen fluoride gas were simultaneously supplied.

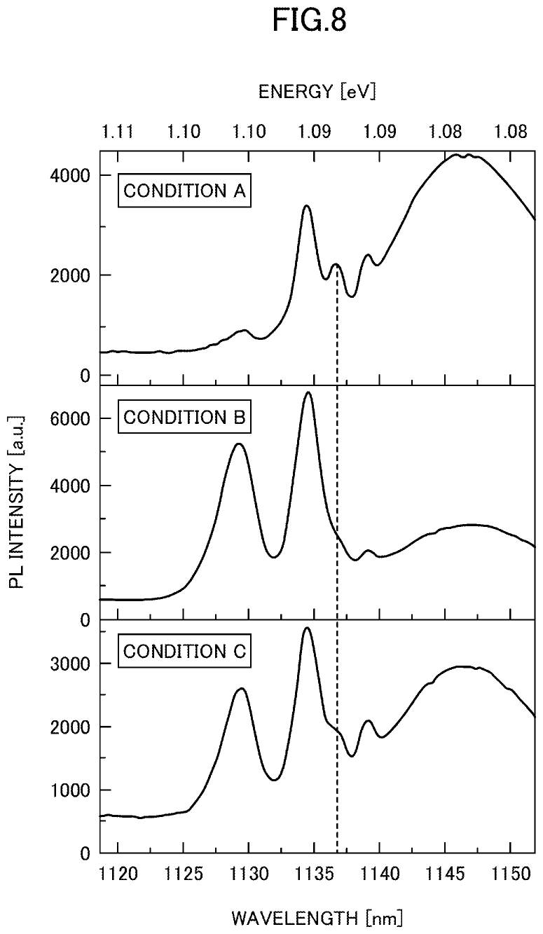

As illustrated in FIG. 8, it was found that a peak of the PL intensity at 1.09 eV was not detected under the conditions B and C, whereas the peak of the PL intensity at 1.09 eV is detected under the condition A. It may be regarded that the peak of the PL intensity at 1.09 eV is a luminescence caused by the fluoride that bonds to the silicon.

The embodiments disclosed herein are to be considered in all respects as illustrative and not restrictive. The embodiments described above may include omissions, substitutions, and modifications in various forms without departing from the scope and spirit of the subject matter of the present disclosure.

In the embodiments described above, the DIPAS gas is used as an example of the aminosilane-based gas, but the present disclosure is not limited to the use of the DIPAS gas. For example, the aminosilane-based gas may be a trisdimethylaminosilane (3DMAS) gas, or a bis-tert-butylaminosilane (BTBAS) gas, or a 2-dimethylamino-2,4,6,8-tetramethylcyclotetrasiloxane gas.

In the embodiments described above, the disilane gas is used as an example of the silane-based gas, but the present disclosure is not limited to the use of the disilane gas. For example, the silane-based gas may be a SiH₄ gas, or a SigHe gas, or a SigH₁₀ gas.

In the embodiments described above, the hydrogen fluoride gas is used as an example of the termination gas, but the present disclosure is not limited to the use of the hydrogen fluoride gas. The termination gas may include an element having an electronegativity lower than the electronegativity of hydrogen (H). The element having the electronegativity lower than the electronegativity of hydrogen may be a halogen, such as chlorine (Cl), bromine (Br), iodine (I), or the like. The element having the electronegativity lower than the electronegativity of hydrogen may be oxygen (O). The termination gas may be a hydrogen halide gas other than the hydrogen fluoride gas, such as HCl gas, HBr gas, HI gas, or the like. In this case, the dangling bond of silicon (Si) in the silicon film is terminated with halogen. The termination gas may be a N₂O gas. In this case, the dangling bond of silicon (Si) in the silicon film is terminated with oxygen (O).

In the embodiments described above, the film forming apparatus is the batch-type apparatus that simultaneously performs processes on a plurality of substrates, but the present disclosure is not limited thereto. For example, the film forming apparatus may be a single wafer type apparatus that processes substrates one by one.

According to the present disclosure, it is possible to reduce defects included in a silicon film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method for forming a silicon film on a substrate, the film forming method comprising:
supplying a silane-based gas and a termination gas to the substrate during a period, wherein
the termination gas includes an element having an electronegativity lower than an electronegativity of hydrogen, and
the supplying includes terminating a dangling bond of silicon in the silicon film with the element.

2. The film forming method as claimed in claim 1, wherein the termination gas is a hydrogen halide gas.

3. The film forming method as claimed in claim 2, wherein the termination gas is a hydrogen fluoride gas.

4. The film forming method as claimed in claim 3, wherein the silane-based gas is a disilane gas.

5. The film forming method as claimed in claim 1, wherein the supplying supplies the silane-based gas to the substrate without supplying the termination gas during a predetermined period.

6. The film forming method as claimed in claim 1, further comprising:
forming a seed layer on the substrate by supplying an aminosilane-based gas to the substrate before the supplying.

7. A film forming apparatus for forming a silicon film on a substrate, the film forming apparatus comprising:
a processing chamber configured to accommodate the substrate;
a gas supply configured to supply a silane-based gas and a termination gas into the processing chamber; and
a controller, wherein
the termination gas includes an element having an electronegativity lower than an electronegativity of hydrogen,
the controller is configured to control the gas supply to perform a process of supplying the silane-based gas and the termination gas to the substrate during a period, and
the process of supplying includes terminating a dangling bond of silicon in the silicon film with the element.
